(19) United States
(12) Patent Application Publication
(10) Pub. No.: US 2014/0110724 A1
(43) Pub. Date: Apr. 24, 2014

(54) PROCESS OF MAKING A STRUCTURE FOR ENCAPSULATING LED CHIPS AND THE LED CHIPS ENCAPSULATION STRUCTURE

(71) Applicants: CHANG WAH ELECTROMATERTIALS INC., Kaohsiung City (TW); CHANG WAH TECHNOLOGY CO., LTD., Kaohsiung City (TW)

(72) Inventor: Chia-Neng Huang, Kaohsiung (TW)

(73) Assignees: CHANG WAH TECHNOLOGY CO.,LTD., Kaohsiung City (TW); CHANG WAH ELECTROMATERTIALS INC., Kaohsiung City (TW)

(21) Appl. No.: 13/656,651

(22) Filed: Oct. 19, 2012

(51) Int. Cl. H01L 33/60; H01L 33/52

(52) U.S. Cl. 257/88; 438/27; 257/E33.059; 257/E33.072

(57) ABSTRACT

A process of making a structure for encapsulating LED chips is provided with punching a reflective substrate into a reflective layer including through holes as reflective cups; punching an insulating substrate into an insulating layer including through holes, a flexible member having top and bottom formed with top and bottom layers of thermoset respectively, and top and bottom coatings formed on the top and bottom layers of thermoset respectively; punching a conductive substrate to form conductive members each having a solder pad and a lead leg; roughening bottom of the reflective layer; roughening top of the conductive substrate; filling an insulating material around the solder pads and the lead legs to form a lead frame; stacking and fastening the reflective layer, the insulating layer, and the lead frame fastened together; and electroplating the stack to form an airtight radiation emitting coating, thereby forming an LED chips encapsulation structure.

### BACKGROUND OF THE INVENTION

1. Field of the Invention The invention relates to semiconductor device packaging and more particularly to a process of making a structure for encapsulating LED chips and the LED chips encapsulation structure.

2. Description of Related Art

A conventional LED chips encapsulation structure 6 is schematically illustrated in FIG. 1 and comprises a reflective substrate 60 having a coated metal thereon as a radiation emitting surface 63, a lead frame 61 formed with a bottom surface of the reflective substrate 60, a light-emitting diode (LED) chip 62 formed on the lead frame 61 in a recess of the reflective substrate 60, and two leads (not numbered) connected the LED chip 62 to anode and cathode of the lead frame 61 respectively.

However, the conventional LED chips encapsulation structure 6 suffered a number of drawbacks. For example, the reflective substrate 60 is made of thermosetting material which cannot effectively exiting heat generated by the LED chip 62 after a relatively long period of operation (i.e., having poor thermal conduction). And in turn, it can damage the reflective substrate 60 and lower light being emitted. Thus, the need for improvement still exists.

### SUMMARY OF THE INVENTION

It is therefore one object of the invention to provide a process of making a structure for encapsulating a plurality of LED chips, comprising the steps of punching a reflective substrate into a reflective layer including a plurality of first through holes arranged as rows of reflective cups; punching an insulating substrate into an insulating layer including a plurality of second through holes arranged in rows, a sheet-like flexible member having top and bottom surfaces formed with top and bottom layers of thermosetting plastic material respectively, and top and bottom coatings formed on the top and bottom layers of thermosetting plastic material respectively; punching a conductive substrate to form a plurality of conductive members arranged in rows wherein each conductive member includes a solder pad and a spaced lead leg; mechanically roughening a bottom of the reflective layer to form a rough surface thereon; mechanically roughening a top of the conductive substrate to form a rough surface thereon; filling an insulating material around the solder pads and the lead legs to form a lead frame; removing the top and bottom coatings of the insulating layer; stacking the reflective layer, the insulating layer, and the lead frame; heating the reflective layer, the insulating layer, and the lead frame for melting the top and bottom layers of thermosetting plastic material; fastening the reflective layer, the insulating layer, and the lead frame fastened together by the top and bottom layers of thermosetting plastic material after cooling; and electroplating the fastened reflective layer, the insulating layer, and the lead frame to form an airtight radiation emitting coating on top and bottom surfaces thereon, thereby forming an LED chips encapsulation structure.

It is another object of the invention to provide an LED chips encapsulation structure comprising a reflective layer comprising a plurality of first through holes arranged in rows, the first through holes being are formed as reflective cups; an insulating layer comprising a sheet-like flexible member having top and bottom surfaces formed with top and bottom layers of thermosetting plastic material respectively, and a plurality of second through holes arranged in rows, the second through holes being are aligned with the first through holes; a lead frame comprising a plurality of conductive members arranged in rows, each conductive member being aligned with both the first and second through holes and including a solder pad and a spaced lead leg; an insulating material filled around the solder pads and the lead legs with tops of the solder pads and the lead legs being adhered to a bottom of the insulating layer; and an airtight radiation emitting coating formed on top and bottom surfaces of the fastened reflective layer, the insulating layer, and the lead frame for covering a top of the reflective cups and bottoms of the solder pads and the lead legs.

The above and other objects, features and advantages of the invention will become apparent from the following detailed description taken with the accompanying drawings.

### BRIEF DESCRIPTION OF THE DRAWINGS

FIG. 1 is a schematic illustration of a conventional LED chips encapsulation structure;

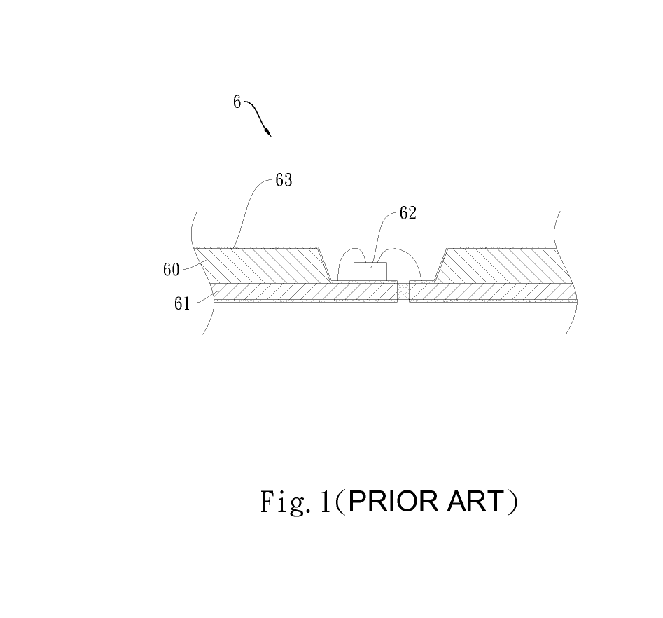

FIG. 2 schematically depicts punching and roughening steps performed on a reflective substrate by a process of making a structure for encapsulating LED chips according to the invention;

FIG. 3 schematically depicts punching step performed on an insulating substrate by the process of the invention;

FIG. 4 schematically depicts punching, roughening and filling steps performed on a conductive substrate by the process of the invention;

FIG. 5 schematically depicts stacking and fastening step performed on the reflective layer, the insulating layer, and the lead frame by the process of the invention;

FIG. 6 schematically depicts electroplating step performed on the fastened reflective layer, the insulating layer, and the lead frame to form an LED chips encapsulation structure by the process of the invention; and

FIG. 7 is a schematic illustration of the LED chips encapsulation structure according to the invention.

### DETAILED DESCRIPTION OF THE INVENTION

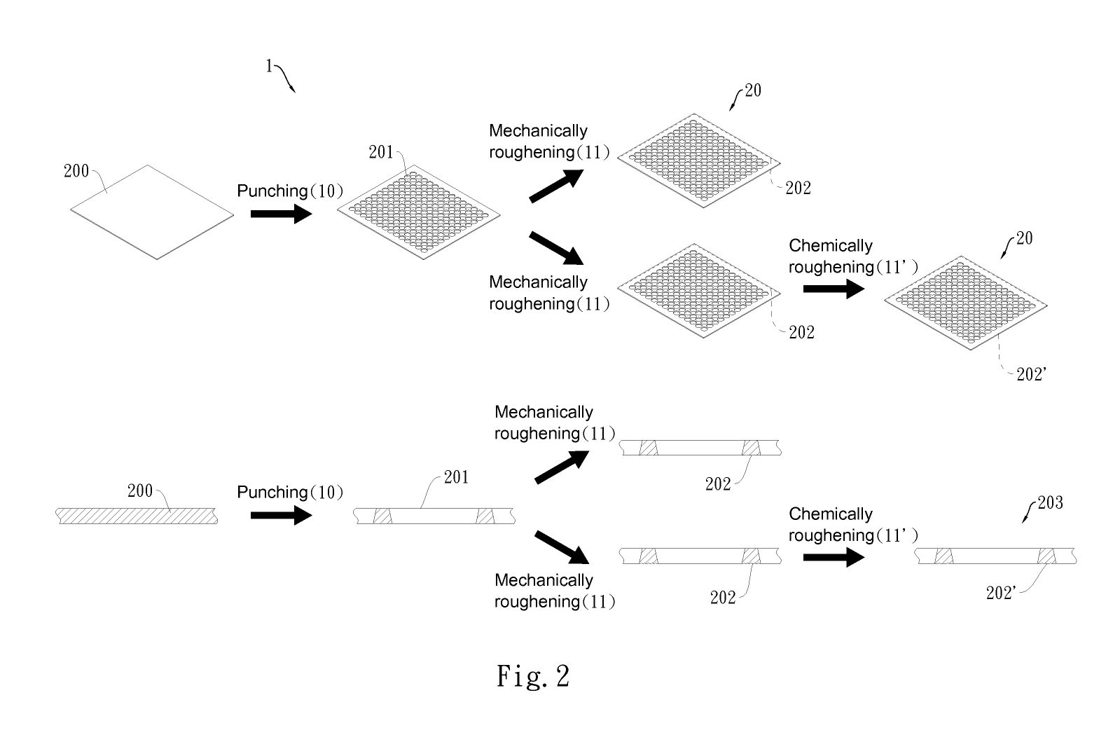

Referring to FIGS. 2 to 6, a process 1 of making a structure for encapsulating LED chips in accordance with the invention is illustrated. The process 1 comprises the following steps:

Punching step 10 is performed on a reflective substrate 200 formed of copper clad as illustrated in FIG. 2. As such, a reflective layer 20 is formed with a plurality of through holes 201 either being cylindrical or tapered downward and arranged in rows. A mechanically roughening 11 is done on a bottom of the reflective substrate 200 so as to form a rough surface 202 on the bottom of the reflective substrate 200. The rough surface 202 can increase contact area. Further, a chemically roughening 11′ is done on the rough surface 202 for forming a rough surface 202′ with increased roughness if the rough surface 202 formed by the mechanically roughening 11 is not sufficiently rough in which the chemically roughening 11′ includes steps of rubbing the rough surface 202 with a predetermined chemical solution, and darkening the rough surface 202 with an oxidizing agent. Finally, the holes 201 are formed as reflective cups 203.

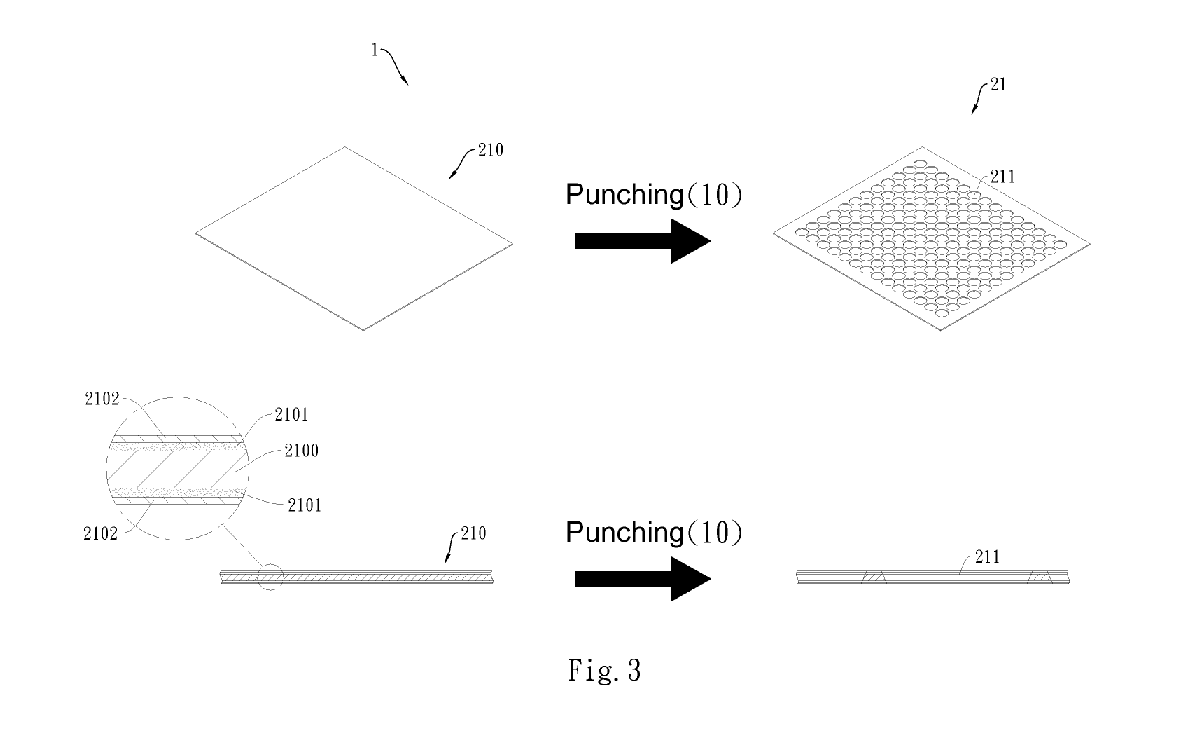

The punching step 10 is also performed on an insulating substrate 210 as illustrated in FIG. 3. The insulating substrate 210 comprises a sheet-like flexible member 2100 formed of polyimide (PI), the flexible member 2100 having top and bottom surfaces formed with top and bottom layers of thermosetting plastic material 2101 respectively, and top and bottom coatings 2102 formed on the top and bottom layers of thermosetting plastic material 2101 respectively. After the punching step 10, the insulating substrate 210 is converted into an insulating layer 21 having a plurality of through holes 211 either cylindrical or tapered downward and arranged in rows.

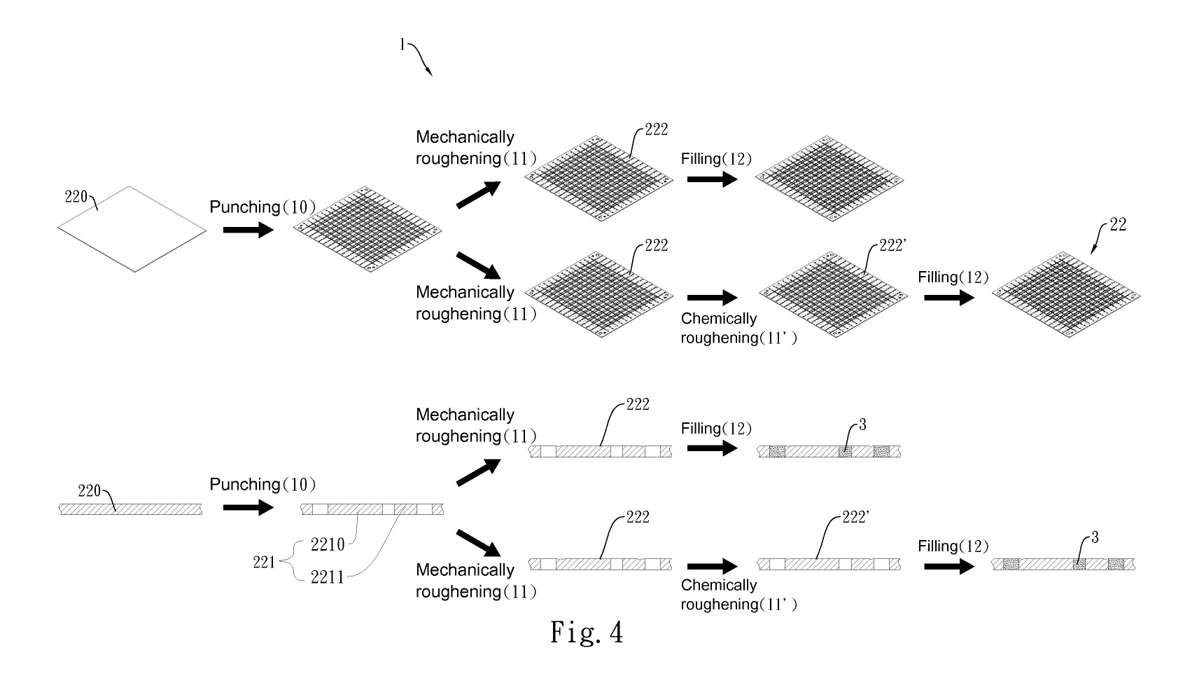

Punching step 10 is also performed on a conductive substrate 220 as illustrated in FIG. 4. As such, the conductive substrate 220 is formed with a plurality of conductive members 221 in rows. Each conductive member 221 includes a solder pad 2210 and a spaced lead leg 2211. Next, a mechanically roughening 11 is done on a top of the conductive substrate 220 so as to form a rough surface 222 on the top of the conductive substrate 220. The rough surface 222 can increase contact area. Further, a chemically roughening 11′ is done on the rough surface 222 for forming a rough surface 222′ with increased roughness if the rough surface 222 formed by the mechanically roughening 11 is not sufficiently rough in which the chemically roughening 11′ includes steps of rubbing the rough surface 222 with a predetermined chemical solution, and darkening the rough surface 222 with an oxidizing agent.

Further, a filling step 12 is performed. In detail, an insulating material 3 either thermosetting plastic material (e.g., epoxy resin or silicon rubber) or thermoplastic material (e.g., polyphthalamide (PPA) or polyamide (PA)) is filled in each hole between the solder pad 2210 and the lead leg 2211 so that a complete insulation can be done between the solder pad 2210 and the lead leg 2211. As a result, a lead frame 22 is formed.

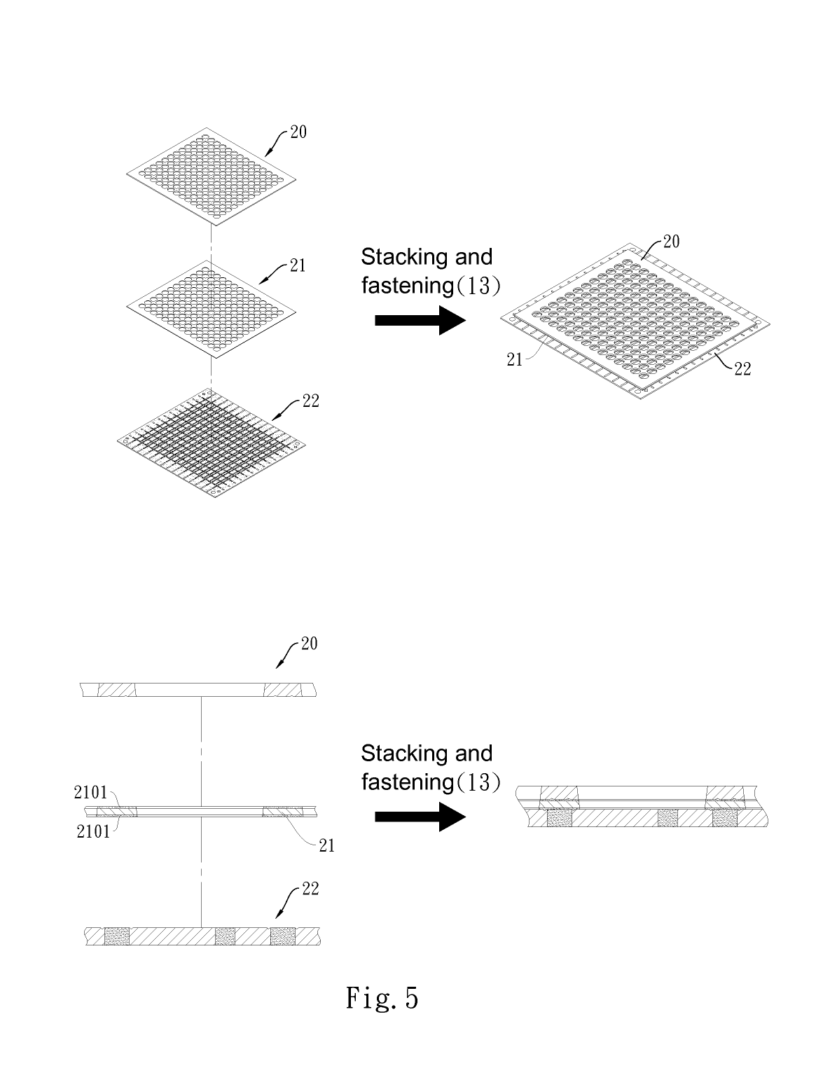

Stacking and fastening step 13 is performed on the reflective layer 20, the insulating layer 21, and the lead frame 22 as illustrated in FIG. 5. In detail, the top and bottom coatings 2102 are removed first. Next, the reflective layer 20, the insulating layer 21, and the lead frame 22 are stacked from top to bottom and heat is applied thereto to melt the top and bottom layers of thermosetting material 2101. As a result, the reflective layer 20, the insulating layer 21, and the lead frame 22 fastened together by the top and bottom layers of thermosetting plastic material 2101 after cooling.

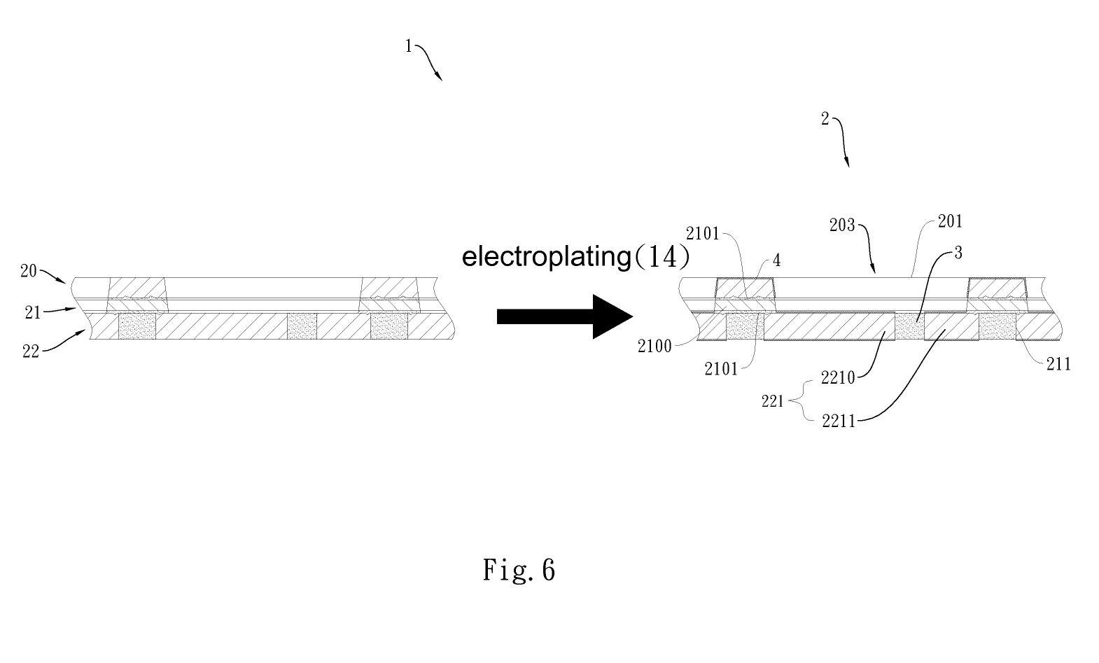

Electroplating step 14 is performed on the fastened reflective layer 20, the insulating layer 21, and the lead frame 22 as illustrated in FIG. 6. In detail, a radiation emitting coating 4 is formed on top and bottom surfaces of the fastened reflective layer 20, the insulating layer 21, and the lead frame 22 for separating the fastened reflective layer 20, the insulating layer 21, and the lead frame 22 from air. The radiation emitting coating 4 is made of a material selected from the group consisting of copper, silver, nickel, palladium, gold, chromium and combinations thereof. The fastened reflective layer 20, the insulating layer 21, and the lead frame 22 and the radiation emitting coating 4 form an LED chips encapsulation structure 2.

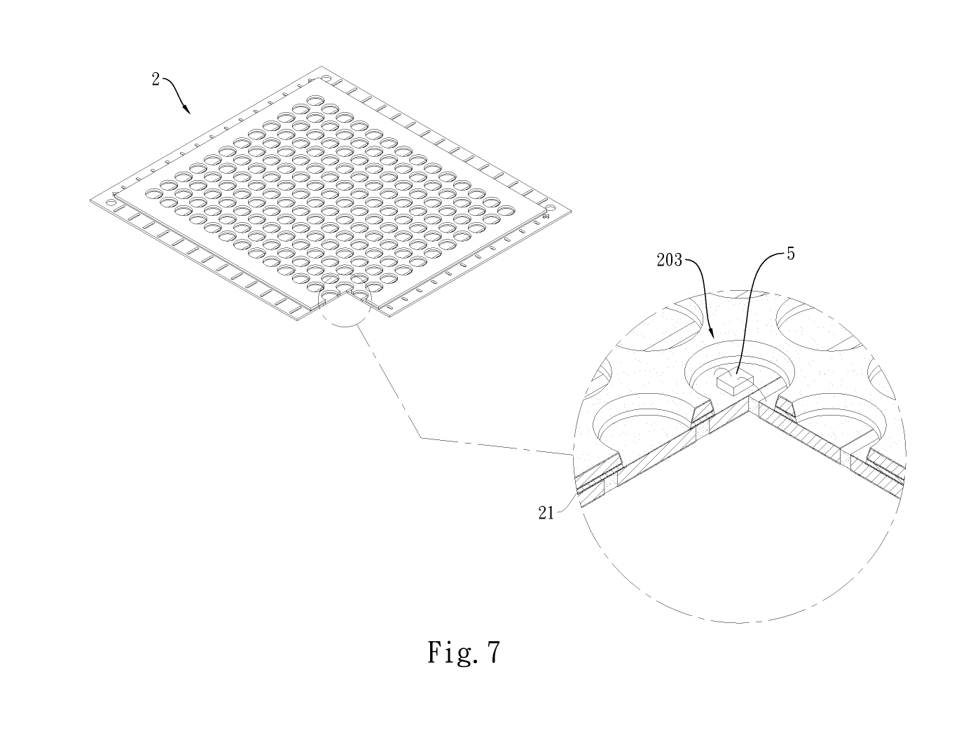

Referring to FIG. 7 in conjunction with FIGS. 2 to 6, the LED chips encapsulation structure 2 produced by the process of the invention is shown. The LED chips encapsulation structure 2 comprises a plurality of LED chips 4 each disposed in the reflective cup 203, the LED chips encapsulation structure 2 including a reflective layer 20 comprising a plurality of through holes 201 either being cylindrical or tapered downward and arranged in rows, the holes 201 being formed as reflective cups 203; an insulating layer 21 comprising a sheet-like flexible member 2100 having top and bottom surfaces formed with top and bottom layers of thermosetting plastic material 2101 respectively, and a plurality of through holes 211 either cylindrical or tapered downward and arranged in rows, the through holes 211 being aligned with the through holes 201; a lead frame 22 comprising a plurality of conductive members 221 arranged in rows, each conductive member 221 being aligned with both the through holes 211 and the through holes 201 and including a solder pad 2210 and a spaced lead leg 2211; an insulating material 3 either thermosetting plastic material (e.g., epoxy resin or silicon rubber) or thermoplastic material (e.g., PPA or PA) filled in each hole between the solder pad 2210 and the lead leg 2211, tops of the solder pad 2210 and the lead leg 2211 being adhered to the bottom of the insulating layer 21; and an airtight radiation emitting coating 4 formed on top and bottom surfaces of the fastened reflective layer 20, the insulating layer 21, and the lead frame 22 for covering the top of the reflective cups 203 and the bottoms of the solder pads 2210 and the lead legs 2211. The LED chips encapsulation structure 2 has the following advantages including improved radiation emitting capability, improved heat resisting capability, durability, improved yield, decreased manufacturing cost, extended lifespan, quick heat dissipating capability, and being less prone to brittleness.

While the invention has been described in terms of preferred embodiments, those skilled in the art will recognize that the invention can be practiced with modifications within the spirit and scope of the appended claims.

What is claimed is:

1. A process of making a structure for encapsulating a plurality of LED chips, the process comprising the steps of:
(a) punching a reflective substrate into a reflective layer including a plurality of first through holes arranged as rows of reflective cups;
(b) punching an insulating substrate into an insulating layer including a plurality of second through holes arranged in rows, a sheet-like flexible member having top and bottom surfaces formed with top and bottom layers of thermosetting plastic material respectively, and top and bottom coatings formed on the top and bottom layers of thermosetting plastic material respectively;
(c) punching a conductive substrate to form a plurality of conductive members arranged in rows wherein each conductive member includes a solder pad and a spaced lead leg;
(d) mechanically roughening a bottom of the reflective layer to form a rough surface thereon;
(e) mechanically roughening a top of the conductive substrate to form a rough surface thereon;
(f) filling an insulating material around the solder pads and the lead legs to form a lead frame;
(g) removing the top and bottom coatings of the insulating layer;
(h) stacking the reflective layer, the insulating layer, and the lead frame;
(i) heating the reflective layer, the insulating layer, and the lead frame for melting the top and bottom layers of thermosetting plastic material;
(i) fastening the reflective layer, the insulating layer, and the lead frame fastened together by the top and bottom layers of thermosetting plastic material after cooling; and
(j) electroplating the fastened reflective layer, the insulating layer, and the lead frame to form an airtight radiation emitting coating on top and bottom surfaces thereon, thereby forming an LED chips encapsulation structure.

2. The process of claim 1, wherein the reflective substrate is formed of copper clad.

3. The process of claim 1, wherein the flexible member is formed of polyimide (PI).

4. The process of claim 1, wherein the thermosetting plastic material is epoxy resin or silicon rubber, and the thermoplastic material is polyphthalamide (PPA) or polyamide (PA).

5. The process of claim 1, further comprising chemically roughening the rough surface on the bottom of the reflective layer for roughness increase and the rough surface on the top of the conductive substrate for roughness increase respectively, and wherein the chemically roughening includes either rubbing the rough surface on the bottom of the reflective layer with a predetermined chemical solution, and darkening the rough surface on the bottom of the reflective layer with an oxidizing agent, or rubbing the rough surface on the top of the conductive substrate with a predetermined chemical solution, and darkening the rough surface on the top of the conductive substrate with an oxidizing agent.

6. The process of claim 1, wherein the radiation emitting coating is made of a material selected from the group consisting of copper, silver, nickel, palladium, gold, chromium and combinations thereof.

7. The process of claim 1, wherein the first through holes are either hollow cylindrical or tapered downward.

8. The process of claim 1, wherein the second through holes are either hollow cylindrical or tapered downward.

9. An LED chips encapsulation structure comprising:
a reflective layer comprising a plurality of first through holes arranged in rows, the first through holes being are formed as reflective cups;
an insulating layer comprising a sheet-like flexible member having top and bottom surfaces formed with top and bottom layers of thermosetting plastic material respectively, and a plurality of second through holes arranged in rows, the second through holes being are aligned with the first through holes;
a lead frame comprising a plurality of conductive members arranged in rows, each conductive member being aligned with both the first and second through holes and including a solder pad and a spaced lead leg;
an insulating material filled around the solder pads and the lead legs with tops of the solder pads and the lead legs being adhered to a bottom of the insulating layer; and
an airtight radiation emitting coating formed on top and bottom surfaces of the fastened reflective layer, the insulating layer, and the lead frame for covering a top of the reflective cups and bottoms of the solder pads and the lead legs.

10. The LED chips encapsulation structure of claim 9, wherein the reflective substrate is formed of copper clad.

11. The LED chips encapsulation structure of claim 9, wherein the flexible member is formed of polyimide (PI).

12. The LED chips encapsulation structure of claim 9, wherein the thermosetting plastic material is epoxy resin or silicon rubber, and the thermoplastic material is polyphthalamide (PPA) or polyamide (PA).

13. The LED chips encapsulation structure of claim 9, wherein the radiation emitting coating is made of a material selected from the group consisting of copper, silver, nickel, palladium, gold, chromium and combinations thereof.

14. The LED chips encapsulation structure of claim 9, wherein the first through holes are either hollow cylindrical or tapered downward.

15. The LED chips encapsulation structure of claim 9, wherein the second through holes are either hollow cylindrical or tapered downward.
